(19) United States
(12) Patent Application Publication
(10) Pub. No.: US 2011/0027719 A1
(43) Pub. Date: Feb. 3, 2011

(54) PHOTOMASK ETCHING METHOD FOR CHEMICAL VAPOR DEPOSITION FILM

(76) Inventor: Pei-Chang WANG, Taichung (TW)

Correspondence Address: Muncy, Geissler, Olds & Lowe, PLLC, 4000 Legato Road, Suite 310, FAIRFAX, VA, 22033, US

(21) Appl. No.: 12/533,077

(22) Filed: Jul. 31, 2009

(51) Int. Cl. G03F 7/20

(52) U.S. Cl. 430/314

(57) ABSTRACT

The present invention discloses a photomask etching method for a CVD film, which comprises steps: exposing an optical resin layer to an ultraviolet ray through a photomask; baking the optical resin layer to gasify the exposed portion of the optical resin layer with the unexposed portion remaining; using a CVD method to form a film on the substrate filling the gasified area and covering the remaining portion of the optical resin layer; exposing the entire film to the ultraviolet ray, and baking the entire substrate at a high temperature to gasify the remaining optical resin layer and remove the film adhering to the remaining optical resin layer to obtain a patterned film. The present invention can achieve higher accuracy of the patterned film with lower equipment cost and lower manufacturing cost.

### FIELD OF THE INVENTION

The present invention relates to a film-patterning method, particularly to a photomask etching method for a CVD film.

### BACKGROUND OF THE INVENTION

The current film etching process may be divided into the dry-etching method and the wet-etching method. The dry-etching method includes the laser etching method and the etching paste printing method. The laser etching method directly uses laser to remove the unwanted portion of a film and obtain a patterned film. The etching paste printing method prints an etching paste on a film and heats the etching paste to remove the unwanted portion of the film and obtain a patterned film.

The wet-etching method forms a photoresist patterning layer on a film firstly. The photoresist patterning layer may be formed via a printing method or a photolithographic-etching method. Next, a chemical solution is used to remove the film not covered by the photoresist patterning layer and obtain a patterned film. The wet-etching method features efficiency and simplicity but suffers from waste liquids and remaining chemicals on products.

In general, the dry-etching method is superior to the wet-etching method due to low equipment cost, low manufacturing cost, and less environmental impact, but the wet-etching method is better than the dry-etching method in the accuracy of the etched lines.

Therefore, the related manufacturers are looking forward to an etching method, which parallels the dry-etching method in lower equipment cost, lower manufacturing cost and less environmental impact, and resembles the wet-etching method in accuracy without chemicals remaining on products.

### SUMMARY OF THE INVENTION

The present invention provides a photomask etching method for a CVD (Chemical Vapor Deposition) film, which adopts a photomask to form patterns without using acid etching, wherefore the present invention has the advantage of the lower equipment cost comparing with the wet-etching method. Besides, the present invention has better accuracy than the dry-etching method and has same accuracy as the wet-etching method. Hence, the present invention can achieve higher accuracy with lower equipment cost, lower manufacturing cost and less environmental impact.

To achieve the abovementioned objective, the present invention proposes a photomask etching method for a CVD film, which comprises steps: providing a substrate, and uniformly applying an optical resin layer on the substrate; exposing the optical resin layer to an ultraviolet ray through a photomask; baking the optical resin layer at an appropriate high temperature to gasify the exposed portion of the optical resin layer with the unexposed portion remaining to obtain a desired pattern defined by the gasified portion; using a CVD method to form a film on the substrate filling the gasified area and covering the remaining portion of the optical resin layer; exposing the entire film to an ultraviolet ray, and baking the entire substrate at an appropriate high temperature to gasify the remaining optical resin layer and remove the film adhering to the remaining optical resin layer to obtain a patterned film.

In the step of exposing the entire film to an ultraviolet ray, if the film is light-permeable, the ultraviolet ray may penetrate the film to expose the remaining optical resin layer. If the substrate is light-permeable, the ultraviolet ray may penetrate the substrate to expose the remaining optical resin layer.

In reducing the equipment cost and manufacturing cost of patterning or wiring a CVD film, the present invention outperforms the conventional wet-etching method in that the present invention is exempted from acid etching. In the accuracy of the patterns, the present invention parallels the conventional wet-etching and outperforms the conventional dry-etching method in that the present invention adopts photolithography to form patterns. Thus, the present invention has the advantages of the wet-etching method and the dry-etching method and is exempted from chemicals remaining on products. Therefore, the products manufactured via the method of present invention can have higher quality.

### BRIEF DESCRIPTION OF THE DRAWINGS

FIG. 1 is a diagram schematically showing that an optical resin layer is uniformly applied to a substrate according to one embodiment of the present invention;

FIG. 2 is a diagram schematically showing that a UV ray exposes the optical resin layer through a photomask according to one embodiment of the present invention;

FIG. 3 is a diagram schematically showing that the exposed portions of the optical resin layer are baked and gasified with the unexposed portions remaining on the substrate according to one embodiment of the present invention;

FIG. 4 is a diagram schematically showing that a film is formed on the substrate with a PECVD method according to one embodiment of the present invention;

FIG. 5 is a diagram schematically showing that an UV ray exposes the remaining portions of the optical resin layer according to one embodiment of the present invention;

FIG. 6 is a diagram schematically showing that the UV-exposed remaining portions of the optical resin layer are baked and gasified to obtain a patterned film according to one embodiment of the present invention; and

FIG. 7 is a diagram schematically showing that an UV ray exposes the remaining portions of the optical resin layer according to another embodiment of the present invention.

### DETAILED DESCRIPTION OF THE PREFERRED EMBODIMENTS

Below, the technical contents of the present invention are described in detail with the embodiments. However, it should be understood that the embodiments are only to exemplify the present invention but not to limit the scope of the present invention.

Refer to FIGS. 1-6. The present invention proposes a photomask etching method for a CVD film, which has lower equipment cost and lower manufacturing cost than the wet-etching method, and has higher pattern accuracy than the dry-etching method.

The method of the present invention comprises the steps described below.

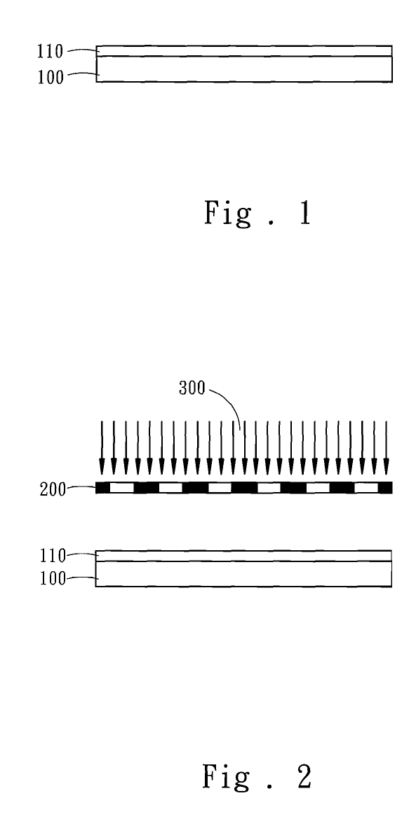

Refer to FIG. 1. Firstly, a substrate 100 is provided, and an optical resin layer 110 is uniformly applied onto the substrate 100. Refer to FIG. 2. An ultraviolet ray 300 passes through the light-permeable areas of a photomask 200 to expose the optical resin layer 110.

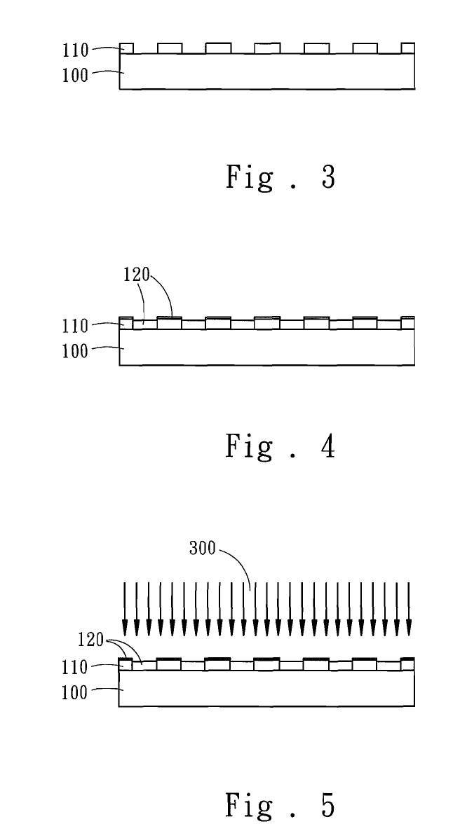

The optical resin layer 110 is a material that will be gasified at a high temperature after the exposure of the ultraviolet ray 300. Refer to FIG. 3. The UV-exposed optical resin layer 110 will be gasified via baking the substrate 100 at an appropriate high temperature, such as at a temperature within a range of 200° C. to 350° C. Thereby, the unexposed areas of the optical resin layer 110 remain on the substrate 100, and the gasified areas form the desired pattern.

Next is undertaken a feature step of the present invention. The patterned optical resin layer 110 will be coated with a film via a CVD (Chemical Vapor Deposition) method. A gas mixture of metal chloride, hydrocarbon and nitrogen is introduced into an airtight chamber containing the substrate 100 and heated to a temperature of 1000° C. under a low-pressure or a vacuum state for a period of time. It should be noted herein that the gas mixture mentioned above is only an exemplification, and that the present invention does not limit the composition of the gas mixture. Refer to FIG. 4. Then, a columnar-crystal film 120 is deposited on the exposed areas of the substrate 100 and the areas of the remaining optical resin layer 110. The columnar-crystal film 120 is made of a material selected from a group consisting of carbide, nitride, oxide, boride or mixtures of the aforementioned materials.

It deserves mentioning that the film 120 may be alternatively formed with a PECVD (Plasma Enhanced CVD) method, which is basically similar to the CVD method but has a faster chemical reaction speed and a shorter manufacturing time than the CVD method. In the PECVD method, a gas mixture of metal chloride, hydrocarbon and nitrogen is introduced into a vacuum chamber containing the substrate 100, and plasma is applied to accelerate the chemical reaction and shorten the manufacturing time.

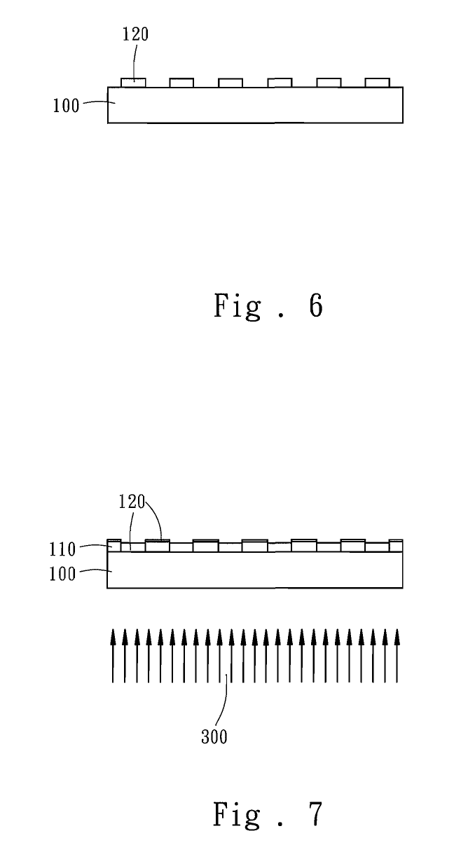

Refer to FIG. 5. Next, the ultraviolet ray 300 is used to expose the optical resin layer 110 remaining on the substrate 100. Refer to FIG. 6. Next, the substrate 100 is heated at an appropriate high temperature, such as at a temperature within a range of 200° C. to 350° C., to gasify the remaining optical resin layer 110 and remove the film 120 adhering to the remaining optical resin layer 110. Thus, only the film 120 directly adhering to the substrate 100 remains. Then, the desired patterned film 120 is obtained.

Refer to FIG. 5 again. In the step of exposing the remaining optical resin layer 110 to the ultraviolet ray 300, if the film 120 is a light-permeable film, such as a transparent conductive film, the ultraviolet ray 300 is arranged above the substrate 100, and the ultraviolet ray 300 penetrates the film 120 to expose the remaining optical resin layer 110. Then, the substrate 100 is baked to gasify the remaining optical resin layer 110. Thus, all the optical resin layer 110 is removed.

Refer to FIG. 7. If the substrate 100 is a light-permeable substrate, such as a transparent glass substrate, the ultraviolet ray 300 is arranged below the substrate 100, and the ultraviolet ray 300 penetrates the substrate 100 to expose the remaining optical resin layer 110. Then, the substrate 100 is baked to gasify the remaining optical resin layer 110. Thus, all the optical resin layer 110 is removed.

In conclusion, the present invention proposes a photomask etching method for a CVD film. The method of the present invention outperforms the wet-etching method in the equipment cost and manufacturing cost because the present invention provides a method without using acid etching process, and outperforms the dry-etching method in the pattern accuracy because the present invention adopts a photomask to form patterns.

What is claimed is:

1. A photomask etching method for a chemical-vapor-deposition film, comprising the steps of:
providing a substrate, and uniformly applying an optical resin layer on said substrate;
exposing said optical resin layer to an ultraviolet ray through a photomask;
baking said optical resin layer to gasify exposed portions of said optical resin layer with unexposed portions remaining;
using a chemical-vapor-deposition (CVD) method to form a film on the substrate filling gasified portions of said optical resin layer and covering remaining portions of said optical resin layer;
exposing said remaining portions of said optical resin layer to said ultraviolet ray; and
baking said substrate to gasify said remaining portions of said optical resin layer and remove said film adhering to said remaining portions of said optical resin layer to obtain a patterned film.

2. The photomask etching method according to claim 1, wherein said chemical-vapor-deposition method includes introducing a gas mixture of metal chloride, hydrocarbon and nitrogen into an airtight chamber containing said substrate, and heating said airtight chamber to a temperature under a low-pressure or a vacuum state for a period of time to deposit a columnar-crystal film on said gasified portions of said optical resin layer and said remaining portions of said optical resin layer.

3. The photomask etching method according to claim 2, wherein said airtight chamber is heated to a temperature of 1000° C.

4. The photomask etching method according to claim 2, wherein said columnar-crystal film is made of a material selected from a group consisting of carbide, nitride, oxide, boride or mixtures thereof.

5. The photomask etching method according to claim 1, wherein said film is formed with a PECVD (Plasma Enhanced CVD) method; a gas mixture of metal chloride, hydrocarbon and nitrogen is introduced into a vacuum chamber containing said substrate, and plasma is applied to accelerate a chemical reaction of forming said columnar-crystal film.

6. The photomask etching method according to claim 1, wherein said film is a light-permeable film, and said ultraviolet ray penetrates said film to expose said remaining portions of said optical resin layer.

7. The photomask etching method according to claim 1, wherein said substrate is a light-permeable substrate, and said ultraviolet ray penetrates said substrate to expose said remaining portions of said optical resin layer.
